(19) United States
(12) Patent Application Publication
(10) Pub. No.: US 2003/0173106 A1
(43) Pub. Date: Sep. 18, 2003

(54) Method for manufacturing transparent conductive panels with a low contact surface impedance

(76) Inventor: Chin-Pei Hwang, Kaohsiung (TW)

Correspondence Address: BIRCH STEWART KOLASCH & BIRCH, PO BOX 747, FALLS CHURCH, VA, 22040-0747, US

(21) Appl. No.: 10/386,418

(22) Filed: Mar. 13, 2003

(30) Foreign Application Priority Data
Mar. 14, 2002 (TW) 091104808

(51) Int. Cl. H05K 1/03; H05K 1/09; G02F 1/1343; G03F 7/16; G03F 7/20; G03F 7/40; C23C 14/24; C23C 14/34

(52) U.S. Cl. 174/255; 174/257; 349/139; 430/312; 430/316; 430/319; 204/192.17; 427/99

(57) ABSTRACT

A simplified manufacturing process for fabricating transparent conductive panels with a low contact surface impedance employs a yellow light and etching technique to form a wiring structure on a single layer transparent conductive film that requires high transparency, and form a wiring structure on a double layer metal film and transparent conductive film for a connecting area to externally connect to a driver circuit. The invention can achieve a higher reliability and lower cost in the processes of fabricating high resolution products.

### FIELD OF THE INVENTION

The present invention relates to transparent conductive panels adopted for use on display devices or photoelectric elements.

### BACKGROUND OF THE INVENTION

The general liquid crystal display (LCD) panels employ Chip on Glass (COG) packaging technique to bond a driver IC on a transparent conductive substrate. As the contact surface impedance between the terminal material of the driver IC (usually a high conductive metal alloy) and the transparent conductive material (usually Indium Tin Oxide—ITO) is generally very high, severe fading of current transmission occurs and signal transmission is delayed. As a result, the display picture often has abnormal phenomena. To remedy this problem, the general approach is to plate a metal film to increase conductivity and reduce the contact surface impedance.

FIG. 1A illustrates the cross section of a conventional LCD device disclosed in U.S. Pat. No. 4,826,297. It has a LCD cell 10 consisting of a lower substrate 100 and an upper substrate 101 made from transparent glass with transparent electrodes 102 and 103 on the inner surfaces thereof. A liquid crystal material 104 is sandwiched between the two substrates. A driving IC chip 11 for the cell 10 is directly connected to the circuit on the conductive glass by means of COG technique. As shown in FIG. 1A, the driving IC chip 11 is connected to a metal film 12 which partly covers the transparent electrode 102. Such a design uses metal film wiring to connect to the terminal of the driving IC to reduce the contact surface impedance of the bonding circuits. Then the metal film wiring is connected to the wiring of the transparent conductive film of the LCD panel. However, in the fabricating process the metal wiring pattern is made to connect the driving IC chip after the wiring pattern on the transparent conductive layer of the lower substrate of the LCD panel has been completed. Thus when the wiring dimension is smaller and demands high precision, errors tend to take place in overlap alignment of the wiring on the connecting area of the transparent conductive layer wiring and metal wiring. As a result, wiring connection defects are prone to occur and wiring impedance increases.

Refer to FIG. 1B for a cross section of a conventional transparent conductive panel disclosed in U.S. Pat. No. 6,037,005. It has a transparent glass 13 with a transparent conductive layer 14 and a metal coating 15 overlapping partly to form an electrode. While such a design can reduce contact surface impedance and enhance wiring conductivity, the metal coating 15 will reflect a portion of light and reduce the total transparency of the display area. Moreover, the electrode in the display device aims at providing a uniform electric field for every pixel. However, the transparent electrode shown in FIG. 1B has a portion of metal overlapped. It causes uneven surface electric field for the pixel electrode and results in poor display uniformity of the display device.

### SUMMARY OF THE INVENTION

In view of the aforesaid disadvantages the invention aims at providing transparent conductive panels that have a low contact surface impedance and a method of manufacturing thereof to overcome the high contact surface impedance problem occurred to the LCD devices without affecting the transparency or display effect of the transparent conductive panels.

Therefore the object of the invention is to provide a double-layer structure for terminal contact wiring. It includes an upper metal film and a lower transparent conductive film. The metal film is connected to a driver IC terminal material to effectively reduce contact surface impedance. The wiring on the display panel uses a single layer transparent conductive film to achieve the required transparency and display effect.

Another object of the invention is to provide a miniaturized wiring for fabricating high resolution display devices. When the wiring for the lower transparent conductive film is fabricated, the metal wiring pattern of the upper layer is used as a mask. Thus wiring connecting defects resulting from erroneous wiring alignment at the connection area may be prevented and manufacturing reliability and yields may be improved.

In order to achieve the foregoing objects, the method for fabricating the transparent conductive panels with a low contact surface impedance according to the invention includes the following steps: first, depositing a transparent conductive film on a transparent substrate; next, depositing a metal film on the transparent conductive film; next, coating a first photoresist layer on the metal film; next, exposing the first photoresist layer with a mask of a first wiring pattern to form the first wiring pattern on the first photoresist layer; then developing the first photoresist layer to form the first wiring pattern on the surface of the first photoresist layer; etching the metal film to form the first wiring pattern on the metal film; removing the residual photoresist; evenly coating a second photoresist layer on the transparent conductive film and the metal film which has the first wiring pattern formed thereon; exposing the second photoresist layer with another mask of a second wiring pattern to form the second wiring pattern on the second photoresist layer; then developing the second photoresist layer to form the second wiring pattern on the surface of the second photoresist layer; etching the transparent conductive film to form the second wiring pattern on the transparent conductive film; finally removing the residual photoresist to complete the invention.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is a fragmentary schematic cross section of a conventional LCD device.

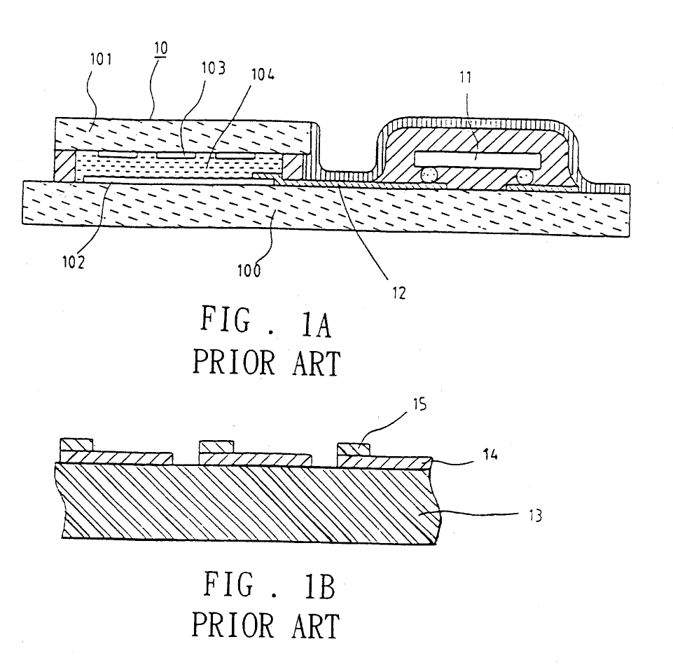

FIG. 1B is a fragmentary schematic cross section of a conventional transparent conductive panel.

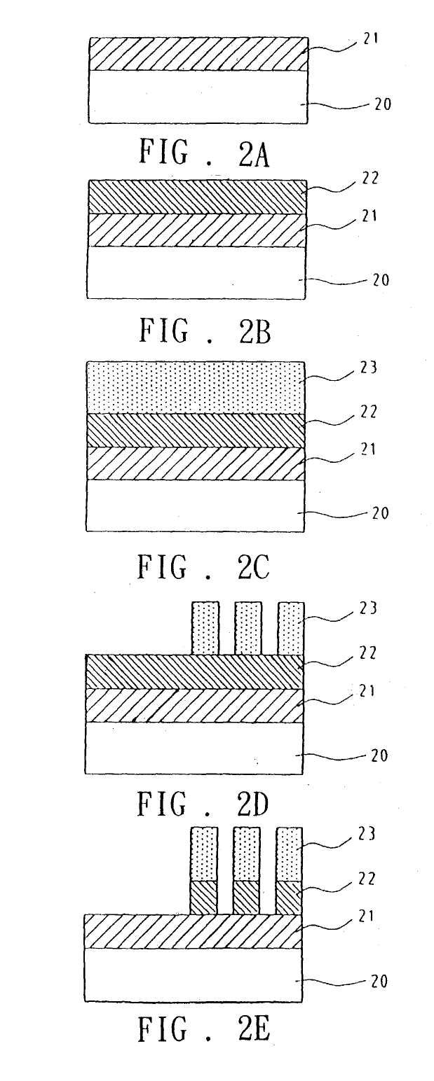

FIGS. 2A through 2J are schematic views of process steps of an embodiment of the invention for fabricating a transparent conductive panel with a low contact surface impedance.

### DETAILED DESCRIPTION OF THE INVENTION

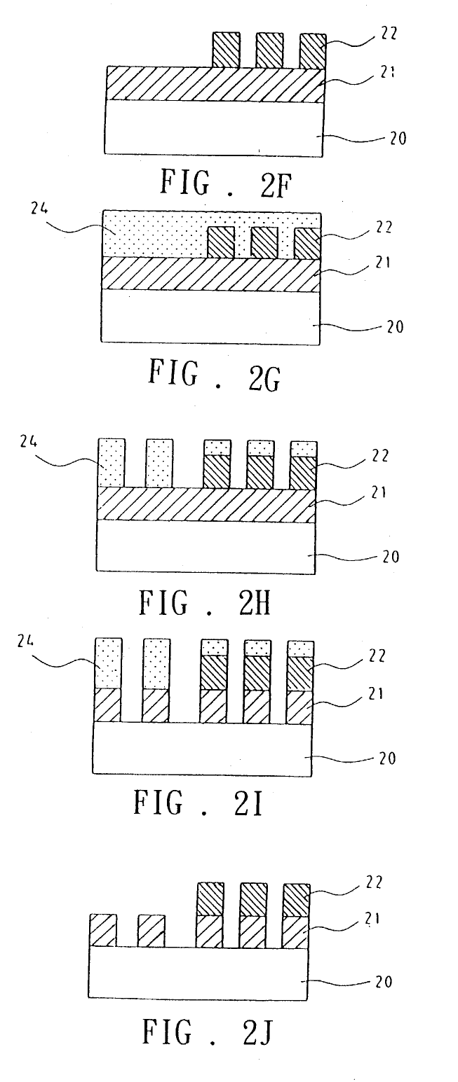

Refer to FIGS. 2A through 2J for the process steps of an embodiment of the invention for fabricating transparent conductive panels with a low contact surface impedance. First, deposit a transparent conductive film 21 by vacuum vaporizing or sputtering on a transparent substrate 20. In the invention, the transparent substrate 20 may be a transparent glass plate or a transparent plastic plate preferably having a thickness about 0.4 mm. The transparent conductive film 21 is a transparent conductive oxide, preferably indium tin oxide (ITO) at a thickness between 1000 and 2000 Å. Next, deposit a metal film 22 also by vacuum vaporizing or sputtering on the transparent conductive film 21. In the invention, the metal film 22 is made from, but not limited to, Ag, Cr, Cu, Al, Au, Fe, Ni, W, Pt, Sn, or alloys or combinations thereof. The metal film 22 has a thickness between 1000 and 2000 Å.

Next, as shown in FIG. 2C, spin coat a first photoresist layer 23 on the metal film 22 at a thickness between 8000 and 10000 Å. Then expose the first photoresist layer 23 through yellow light by means of a mask which has a first wiring pattern formed thereon to form the first wiring pattern on the first photoresist layer 23. Then develop the first photoresist layer 23 to form the first wiring pattern on the surface of the first photoresist layer 23 as shown in FIG. 2D. The residual first photoresist layer 23 serves as the mask for etching the metal film 22 in a unidirectional and normal fashion to form the first wiring pattern on the metal film 22 as shown in FIG. 2E. The residual photoresist is removed by conventional oxygen ashing method or through acetone as shown in FIG. 2F.

Referring to FIG. 2G, evenly coat a second photoresist layer 24 on the transparent conductive film 21 and the metal film 22 which has the first wiring pattern formed thereon. The second photoresist layer 24 has a thickness between 8000 and 10000 Å. Next, expose the second photoresist layer 24 through yellow light by means of another mask which has a second wiring pattern formed thereon to form the second wiring pattern on the second photoresist layer 24. Then develop the second photoresist layer 24 to form the second wiring pattern on the surface of the second photoresist layer 24 to obtain a structure as shown in FIG. 2H.

Then the residual second photoresist layer 24 serves as the mask for etching the transparent conductive film 21 in a unidirectional and normal fashion to form the second wiring pattern on the transparent conductive film 21 as shown in FIG. 2I. Finally, the residual photoresist is removed as discussed before to complete the transparent conductive panel with a low contact surface impedance as shown in FIG. 2J.

The characteristics of the invention are to employ yellow light and etching processes to form a wiring structure on a single layer transparent conductive film that requires high transparency (such as a display area), and form a wiring structure on a double layer metal film and transparent conductive panel for the connecting area (i.e. terminal connecting area) to externally connect to the driver circuit (such as driver chip). By means of the invention, the problem of high contact surface impedance between the conventional transparent conductive panel and externally connecting driver circuit can be overcome without affecting the transparency of the transparent conductive panel. Another feature of the invention is to use a manufacturing process for high resolution display devices to fabricate the transparent conductive panel. The invention employs two yellow light and etching processes. The first time is to remove the upper metal film of the display area and etch the required wiring pattern on the upper metal film of the terminal connecting area. The second time is to etch another wiring pattern on the transparent conductive film of the display area. Thus the invention can synchronously fabricate the wiring patterns for the display area and the terminal connecting area of the transparent conductive panel. Comparing with the complex fabrication processes of conventional techniques, the invention has a great improvement and can achieve a higher reliability, lower cost and is suitable for mass production, especially in the processes of fabricating high resolution products.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A method for manufacturing transparent conductive panels that have a low contact surface impedance, comprising steps of:
(A) depositing a transparent conductive film on a transparent substrate;
(B) depositing a metal film on the transparent conductive film;
(C) coating a first photoresist layer on the metal film;
(D) exposing the first photoresist layer by yellow light through a mask which has a first wiring pattern to form the first wiring pattern on the first photoresist layer;
(E)developing the first photoresist layer to form the first wiring pattern on the first photoresist layer;
(F) etching the metal film to form the first wiring pattern on the metal film;
(G) removing the residual photoresist;
(H) coating a second photoresist layer on the transparent conductive film and the metal film which has the first wiring pattern formed thereon;
(I) exposing the second photoresist layer by yellow light through another mask which has a second wiring pattern to form the second wiring pattern on the second photoresist layer;
(J) developing the second photoresist layer to form the second wiring pattern on the second photoresist layer;
(K) etching the transparent conductive film to form the second wiring pattern on the transparent conductive film; and
(L) removing the residual photoresist.

2. The method of claim 1, wherein the step (A) of depositing a transparent conductive film on a transparent substrate is achieved through a vacuum evaporating or a vacuum sputtering process.

3. The method of claim 1, wherein the step (B) of depositing a metal film on the transparent conductive film is achieved through a vacuum evaporating or a vacuum sputtering process.

4. The method of claim 1, wherein the transparent substrate is a transparent glass panel or a transparent plastic panel.

5. The method of claim 1, wherein the transparent conductive film is a transparent conductive oxide.

6. The method of claim 5, wherein the transparent conductive oxide is indium tin oxide.

7. The method of claim 1, wherein the metal film is made of Ag, Cr, Cu, Al, Au, Fe, Ni, W, Pt, Sn, or alloys or combinations thereof.

8. The method of claim 1, wherein the transparent substrate has a thickness ranging from about 0.1 to 1.1 mm.

9. The method of claim 1, wherein the transparent conductive film has a thickness ranging from 500 to 2000 Å.

10. The method of claim 1, wherein the metal film has a thickness ranging from 1000 to 2000 Å.

11. The method of claim 1, wherein the first photoresist layer has a thickness ranging from 5000 to 10000 Å.

12. The method of claim 1, wherein the second photoresist layer has a thickness ranging from 5000 to 10000 Å.

13. A transparent conductive panel having a low contact surface impedance, comprising:
a transparent substrate;
a transparent conductive film covering the transparent substrate and having a second wiring pattern formed thereon; and
a metal film covering the transparent conductive film and having a first wiring pattern formed thereon.

14. The transparent conductive panel of claim 13, wherein the transparent substrate is a transparent glass panel or a transparent plastic panel.

15. The transparent conductive panel of claim 13, wherein the transparent conductive film is a transparent conductive oxide.

16. The transparent conductive panel of claim 15, wherein the transparent conductive oxide is indium tin oxide.

17. The transparent conductive panel of claim 13, wherein the metal film is made of Ag, Cr, Cu, Al, Au, Fe, Ni, W, Pt, Sn, or alloys or combinations thereof.

18. The transparent conductive panel of claim 13, wherein the transparent substrate has a thickness ranging from about 0.1 to 1.1 mm.

19. The transparent conductive panel of claim 13, wherein the transparent conductive film has a thickness ranging from 500 to 2500 Å.

20. The transparent conductive panel of claim 13, wherein the metal film has a thickness ranging from 1000 to 2000 Å.
